(19) United States
(12) Patent Application Publication
(10) Pub. No.: US 2009/0063081 A1
(43) Pub. Date: Mar. 5, 2009

(54) BRIDGE SENSOR CALIBRATION

(75) Inventor: GANG XU, SHANGHAI (CN)

Correspondence Address: KL IP CONSULTING, 20 LONG DR., WESTBOROUGH, MA, 01581, US

(73) Assignee: ACCEL SEMICONDUCTOR (SHANGHAI) LIMITED, Shanghai (CN)

(21) Appl. No.: 12/196,328

(22) Filed: Aug. 22, 2008

Related U.S. Application Data
(60) Provisional application No. 60/967,391, filed on Sep. 5, 2007.

(51) Int. Cl. G01R 35/00

(52) U.S. Cl. 702/107

(57) ABSTRACT

An integrated circuit chip for calibrating a bridge sensor is described. The integrated circuit (IC) comprises a voltage regulator for providing a voltage to drive the sensor and the integrated circuit; a temperature sensor for measuring a temperature of the environment; a programmable gain amplifier having inputs connected to the sensor for receiving differential outputs of the sensor; a programmable offset generator for performing analog coarse calibration of the bridge sensor offset by providing an offset value to the input of the programmable gain amplifier; an analog multiplex selects either the programmable gain amplifier output or the environment temperature measurement from the temperature sensor as output; a high resolution analog-to-digital converter quantizes the output of the analog multiplex; a processor for performing digital fine calibration by calculating calibration coefficients for a selected set of parameters including the offset of the bridge sensor, temperature coefficients of the bridge sensor sensitivity and nonlinearity of the sensitivity; and a digital memory unit for storing the coarse calibration offset value and the calculated fine calibration coefficients.

### CROSS REFERENCE TO RELATED APPLICATIONS

This application claims priority under 35 U.S.C. § 119(e) to provisional patent application No. 60/967,391, filed Sep. 5, 2007, the disclosure of which is hereby incorporated by reference herein.

### STATEMENT REGARDING FEDERALLY SPONSORED RESEARCH

Not Applicable.

### FIELD OF THE INVENTION

This description relates generally to sensor calibration and more particularly, the description relates to a bridge sensor, such as wheatstone bridge resistance sensor calibration.

### SUMMARY

In general, in one aspect, the invention features an integrated circuit (IC) for calibrating a bridge sensor, which comprises a voltage regulator for providing a voltage to drive the sensor and the integrated circuit; a temperature sensor for measuring a temperature of the environment; a programmable gain amplifier having inputs connected to the sensor for receiving differential outputs of the sensor; a programmable offset generator for performing analog coarse calibration of the bridge sensor offset by providing an offset value to the input of the programmable gain amplifier; an analog multiplex selects either the programmable gain amplifier output or the environment temperature measurement from the temperature sensor as output; a high resolution analog-to-digital converter quantizes the output of the analog multiplex; a processor for performing digital fine calibration by calculating calibration coefficients for a selected set of parameters including the offset of the bridge sensor, temperature coefficients of the bridge sensor sensitivity and nonlinearity of the sensitivity; and a digital memory unit for storing the coarse calibration offset value and the calculated fine calibration coefficients.

Implementation of the invention may include one or more of the following features. The voltage regulator in the integrated circuit chip provides a constant voltage with linear temperature coefficient. The programmable offset generator in the integrated circuit chip is a digital-to-analog converter. The high resolution analog-to-digital converter in the integrated circuit chip has at least 18 bits. The digital memory unit in the integrated circuit chip is chosen from the group consisting of an electrically erasable programmable ROM (EEPROM), a one-time programmable (OTP), and a multi-time programmable (MTP) memory. The processor in the integrated circuit chip calculates the calibration coefficients based on a curve equation representing a relationship between bridge sensor output and environment variables including environment temperature and the calculated calibration coefficients are stored in the digital memory unit as a look-up table. The integrated circuit chip further comprises a circuitry for controlling the calculation steps and flow. The offset value in the integrated circuit chip provides a calibrating signal summing with the sensor output differential output signals at the inputs of the programmable gain amplifier. The offset value for coarse calibration in the integrated circuit chip is determined according to the full swing input of analog-to-digital converter. The selected set of parameters in the integrated circuit chip comprises second order or higher nonlinearity of the parameters chosen from the group consisting of bridge supply, bridge bias, the programmable gain amplifier, offset, and digital-to-analog converter.

In general, in another aspect, the invention features a method for calibrating a bridge sensor using an integrated circuit (IC), which comprises providing a constant voltage to the sensor and the integrated circuit, wherein the voltage is from a voltage regulator residing on the integrated circuit; adding an offset signal to the input of a programmable gain amplifier on the integrated circuit to the differential output of the bridge sensor, wherein the offset value is stored in a digital memory unit of the integrated circuit; setting the integrated circuit environment variables to a plurality of values; measuring, the quantized by an analog-to-digital converter, at least one of the differential output of the bridge sensor calibrated in the analog domain and amplified by the programmable gain amplifier and a temperature reading from a temperature sensor on the integrated circuit, to obtain a plurality of measurements corresponding to the plurality of environment variables; calculating, in the digital domain, calibration coefficients for a selected set of parameters including the offset of the bridge sensor, temperature coefficients of the bridge sensor sensitivity and nonlinearity of the sensitivity; and storing the calculated calibration coefficients in the digital memory unit; adding an offset signal to the input of a programmable gain amplifier on the integrated circuit to the differential output of the bridge sensor, wherein the offset value is stored in a digital memory unit of the integrated circuit; setting the integrated circuit environment variables to a plurality of values; measuring quantized, by an analog-to-digital converter, at least one of the differential output of the bridge sensor calibrated in the analog domain and amplified by the programmable gain amplifier or a temperature reading from a temperature sensor on the integrated circuit, wherein the measurements corresponding to the plurality of environment variables; calibrating, in the digital domain, by calculating, in digital domain, calibration coefficients for a selected set of parameters including the offset of the bridge sensor, temperature coefficients of the bridge sensor sensitivity and nonlinearity of the sensitivity; and storing the calculated calibration coefficients in the digital memory unit.

Implementation of the invention may include one or more of the following features. The voltage from the voltage regulator has linear temperature coefficient characteristic. The digital domain calculating is performed by fitting a curve representing a relationship between bridge sensor output and environment variables to the plurality of measurements. The calculated calibration coefficients are stored in the digital memory unit as a look-up table. The selected set of parameters comprises second order or higher nonlinearity of the parameters chosen from the group consisting of bridge supply, bridge bias, the programmable gain amplifier, offset, and digital-to-analog converter.

### BRIEF DESCRIPTION OF THE DRAWINGS

This invention is described with particularity in the detailed description. The above and further advantages of this invention may be better understood by referring to the following description in conjunction with the accompanying drawings, in which like numerals indicate like structural elements and features in various figures. The drawings are not necessarily to scale, emphasis instead being placed upon illustrating the principles of the invention.

FIG. 1 illustrates a functional block diagram of an IC signal conditioning chip.

FIG. 2 illustrates an analog coarse sensor calibration procedure.

FIG. 3 illustrates a portion of a digital fine sensor calibration procedure.

FIG. 4 illustrates another portion of the digital fine sensor calibration procedure.

FIG. 5 illustrates the IC signal conditioning chip and its connection to a sensor.

### DETAILED DESCRIPTION

Reference will now be made in detail to certain embodiments of the invention, one or more examples of which are illustrated in the accompanying drawings. Each example is provided by way of explanation of the invention, not limitation of the invention. It will be apparent to those skilled in the art that modifications and variations can be made in the present invention without departing from the scope or spirit thereof. For instance, features illustrated or described as part of one embodiment may be used on another embodiment to yield a still further embodiment. Thus, it is intended that the present invention covers such modifications and variations that come within the scope of the present disclosure, including the appended claims.

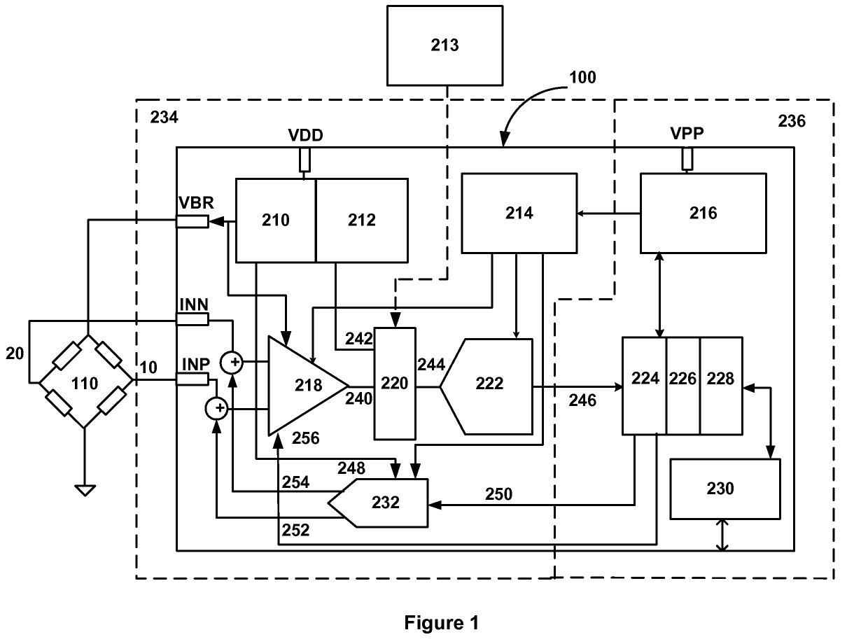

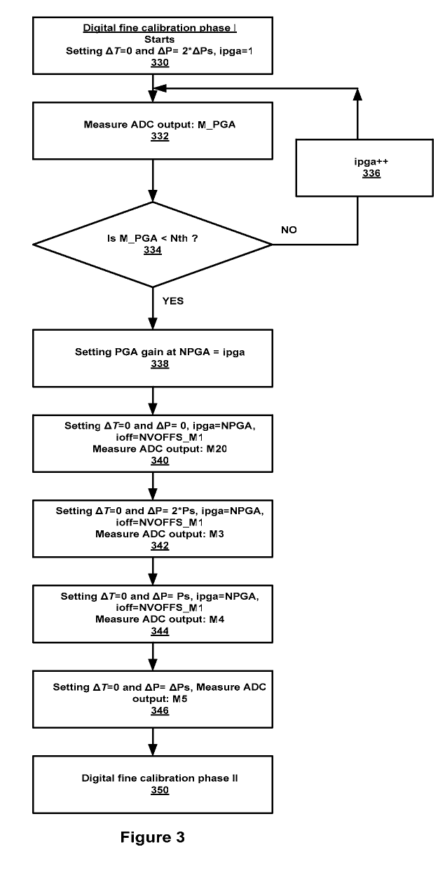

FIG. 1 shows a functional block diagram of an integrated circuit (IC) signal conditioning chip 100. For simplicity, not all pins of the chip 100 are shown in FIG. 1. A complete list of pins and their description will be provided in FIG. 3 below. As shown in dotted line in FIG. 1, the functional signal processing of the integrated circuit (IC) signal conditioning chip 100 comprises an analog processing block 234 and a digital processing block 236. The integrated circuit (IC) signal conditioning chip 100 takes two analog differential outputs 10 and 20 from bridge sensor 110, at its positive input (INP) pin and negative input (INN) pin. The bridge sensor 110 is driven by a voltage regulator 210 residing on the integrated circuit (IC) signal conditioning chip 100 via pin VBR. The on-chip voltage regulator 210 provides voltages for both the bridge sensor 110 and various circuitries on the integrated circuit (IC) signal conditioning chip 100. In the example integrated circuit (IC) signal conditioning chip 100, the on-chip voltage regulator 210 provides voltage for the digital processing block via pin VDD and functions as power supply for the digital memory component 216 which may be in the form of electrically erasable programmable ROM (EEPROM), one-time programmable (OTP) or multi-time programmable (MTP) memory. The integrated circuit (IC) signal conditioning chip 100 comprises an on-chip clock source 214 such as an RC oscillator or a crystal oscillator for providing a time base to execute various instructions and to clock the ADC (analog-to-digital) 222 and DAC (digital-to-analog) 232 converters.

In the example, the on-chip voltage regulator 210 is a Low dropout regulator (LDO) which provides a constant voltage with linear temperature coefficient characteristic from a constant voltage reference source. A LDO's output voltage variation is due primarily to a variation in the temperature of the constant voltage reference source and the differential amplifier characteristics. The LDO 210 can thus be designed to provide a constant voltage with linear temperature coefficient characteristic desirable for good performance of the integrated circuit (IC) signal conditioning chip 100. Known solutions use an external regulator to drive the sensor and/or the signal conditioning chip, which requires the external voltage source to have good performance in temperature and power supply drop. The on-chip LDO voltage regulator 210 in the example offers much large power supply range and has better tolerance to power supply ripple or drop. The voltage with linear temperature coefficient characteristic provided by LDO 210 is utilized not only for driving the bridge sensor 110 but also for facilitating calibrating various sensor parameters which is described in more detail below.

In the example, integrated circuit (IC) signal conditioning chip 100 comprises an on-chip temperature sensor 212 which measures the environment variables such as the temperature and the pressure. It should be noted that an external temperature sensing means 213 such as an external diode or a thermistor may be used instead.

In operation, after the bridge sensor 110 is connected to the integrated circuit (IC) signal conditioning chip 100 via the two pins INP and INN, the on-chip voltage regulator 210 provides a voltage, in one example, a constant voltage with linear temperature coefficient characteristic, to excite the bridge sensor 110. The physical energy (tension or compression, for example) causes a change in resistance of the bridge sensor 110 which shows up as a voltage differential between the two legs (10 and 20) of the bridge. Since resistors react to temperature, the sensor output drift because of the thermal error can be significant, and has to be calibrated. The bridge output offset induced by unbalanced bridge due to sensor manufacture process variance, for example, the industrial fabrication, causes sensor-to-sensor offset variations which has to be removed.

Referring back to FIG. 1, the differential outputs 10 and 20 are amplified by the programmable gain amplifier (PGA) 218. PGA 218 is driven by the on-chip voltage regulator 210 and clocked by on-chip clock source 214. The amplified PGA 218 output signal 240 is provided, along with sensed environment temperature signal 242 from on-chip temperature sensor 212, as inputs to a multiplexer 220. The multiplexer 220 selects either PGA output signal 240 or temperature signal 242 as input signal 244 to an analog-to-digital (ADC) converter 222 where the signal 244 will be quantized and then being outputted from analog block 234 as digital signal 246 to be inputted into digital block 236. In the example, ADC 222 is a Sigma-delta ADC with at least 18 bit, for example, 18˜24 bits. The ADC 222 is chosen to have higher resolution than those most commonly seen on the market. The high resolution ADC 222 provides better quantized, more accurate digital signal 246 for digital signal processing in the digital processing block 236.

The input 246 to the digital processing block 236 is first processed in an arithmetic logic unit (ALU) 224, an on-chip processor, to perform general mathematic operations like addition, multiplication etc, which is controlled by a flow state machine (FSM) 226. The flow state machine (FSM) depends on a mathematic algorithm selected to calculate the calibration coefficients. Memory 228 stores the internal/intermediate results for the digital signal processing.

The on-chip memory component 216, for example, an electrically erasable programmable ROM (EEPROM), a one-time programmable (OTP) or a multi-time programmable (MTP) memory, stores calculated coefficients for sensor calibration to compensate temperature induced drifts and nonlinearities including second or higher order nonlinearities. These stored calibration coefficients will be used in the calculation process performed in the arithmetic logic unit (ALU) 224.

Various sensor parameters can be calibrated. For example, bridge output offset; temperature coefficients of the bridge supply voltage; temperature coefficients of the offset of the sensor bridge output; temperature coefficients of the circuit offset and gain; nonlinearity of the temperature sensor; nonlinearity of the sensor bridge output. The nonlinearities can be second order or higher. Depending on which sensor parameters are selected for calibration, the calculated coefficients for the selected sensor parameter calibration can be stored in the on-chip memory component 216.

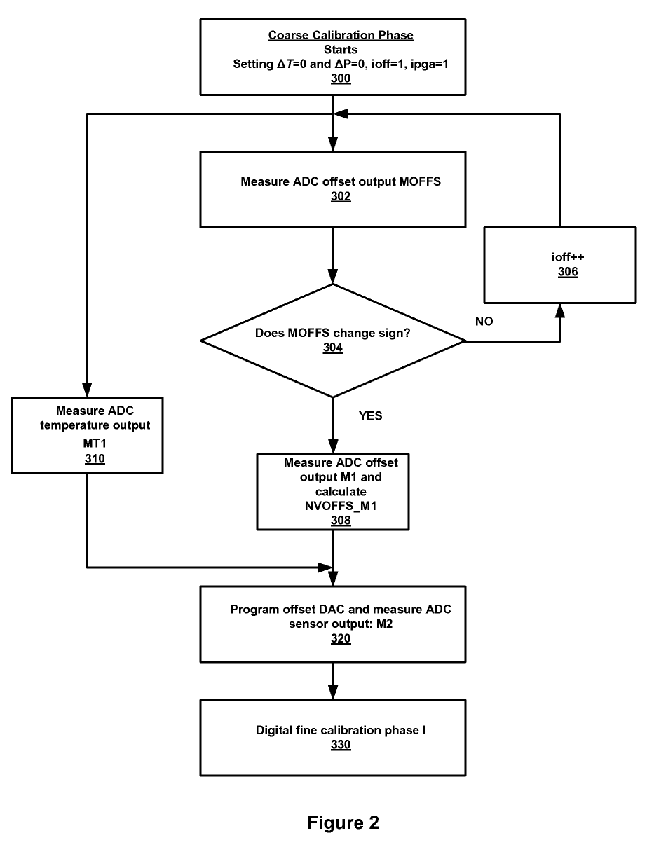

A digital interface circuit 230 is also included in the integrated circuit (IC) signal conditioning chip 100 to communicate with an external Microcontroller Unit (MCU) (not shown). In the example, the interface circuit 230 is based on I2C standard such as a 2-wire serial interface standard for communicating SCL clock and SDA data information with the external MCU. In one example, the serial digital interface 230 is utilized, in a calibration procedure described in more detail below in connection with FIG. 2, to program the registers of the on-chip memory component 216 of the integrated circuit (IC) signal conditioning chip 100—the external MCU stores calibration coefficients of the selected sensor parameters into the on-chip memory component 216 and initializes the flow state machine (FSM) 226 based on selected calibration algorithm.

In a high-temperature or other harsh environments, flowing signal in analog domain causes a lot of problems such as signal degradation. The integrated circuit (IC) signal conditioning chip 100 of FIG. 1 provides high accuracy sensor calibration by minimizing calibration operation in analog signal processing block 234 while utilizing a high resolution ADC 222 to accommodate that the majority of calibration operation is conducted in the digital processing block 236 thus providing high accurate signal processing in the digital domain.

In operation, the only physical calibration performed in analog domain is the bridge output offset correction to bring the sensor's dynamic range in line with the full swing input of ADC 222 and the digital signal processing margin. For all the other sensor parameters, for example, first and second order bridge offset temperature coefficients, bridge sensitivity, first and second order sensitivity temperature coefficients, and sensitivity nonlinearity, the calibration will be performed in digital domain in digital processing block 236 of FIG. 1. In other words, the only static calibration—sensor-to-sensor offset variation, which is termed coarse calibration herein, is performed once in analog domain and the dynamic temperature induced variations calibration, which is termed fine calibration herein, will be performed exclusively in digital domain. The design allows the analog circuit to be designed much simpler thus allows the on-chip voltage regulator 210 to have much lower power supply, a very desirable characteristic suitable for sub-micron circuit design.

In one example, the bridge output offset calibration—the coarse calibration is performed by a programmable offset generator 232. In implementation, programmable offset generator 232 is constructed as an offset DAC (digital-to-analog-converter) which allows digital adjustment of the analog component or function. Digital adjustment permits the set of values to be stored in digital memory 216, instead of analog memory. The offset DAC 232 enables multiplication of an analog reference voltage 248, by a digital coarse offset value 250 stored in the digital memory 216 and provided by the arithmetic logic unit (ALU) 224, without converting the analog reference voltage 248 into the digital domain. The outputs 252 and 254 of the offset DAC 232 are added to the bridge sensor differential outputs 10 and 20 respectively to adjust the two inputs of the PGA 218. After coarse offset calibration, the corrected differential outputs of the bridge sensor 110 are sent to PGA 218 for amplification. The initial bridge output offset due to unbalanced bridge can be very large. Since the purpose of the coarse offset calibration is to bring the sensor's dynamic range in line with the full swing input of ADC 222 and the digital signal processing margin, the stored coarse calibration values 250 are determined based on the specification of the ADC 222, sensor output range and other measurements such as environmental temperature and pressure from the calibration process.

The coarsely calibrated inputs to the PGA 218 generates output 240, which is fed to, along with the on-chip temperature-sensor reading 242, to the multiplexer 220. Once digitized by the high resolution ADC 222, the output 244 of the multiplexer 220, which is either the amplified sensor output 240 or the temperature reading 242, is sent to the digital processing block 236 for further fine calibration processing.

In essence, in fine calibration, calculation of the calibration coefficient is performed in a calibration procedure by fitting a selected calibration equation to a series of measurement data points. A larger number of measurement points makes for a better curve fit accuracy, but increases the measurement cost. The calculated calibration coefficients can be stored in the digital memory 216, such as a look-up table. The fine calibration can include, as shown in FIG. 1, determining a tuning value for the PGA 218 gain. The tuning value 256 can be stored in the register of the digital memory component 216, controllably supplied by the arithmetic logic unit (ALU) 224. In one example, the calibration curve equation representing a pressure bridge sensor output and selected calibration parameters is as follows:

Vₛₑₙₛₑ=V_{BR0}·(1+TC_{BR}·ΔT)·S₀·(1+TC_{1,S}·ΔT+TC_{2,S}·ΔT²)·(1+Kₛ·ΔP)·ΔP+V_{off,0}·(1+TC_{1,o}·ΔT+TC_{2,o}·ΔT²) (1)

Table 1 below defines symbols used in calibration curve equations.

TABLE 1
Calibration equation symbol definition

| Symbol | Explanation |
|---|---|
| V_{BR} | The bridge supply voltage |
| V_{BR0} | The bridge supply voltage at T₀ |
| Vₛₑₙₛₑ | The equivalent output voltage of the sensor |
| T₀ | The room/initial temperature |
| ΔT | The temperature change from T₀ |
| P₀ | The initial pressure |
| ΔP | The pressure change from P₀, normalized to Pₘₐₓ |
| TC_{BR} | The bridge supply voltage temperature coefficient |
| S₀ | The bridge sensitivity at T₀ |
| K_{S} | The second order factor of the sensitivity |
| TC_{1, S} | The first order temperature coefficient of the sensitivity |
| TC_{2, S} | The second order temperature coefficient of the sensitivity |
| V_{off0} | The offset voltage from the bridge at T₀ and P₀ |
| TC_{1, O} | The first order temperature coefficient of the offset voltage |
| TC_{2, O} | The second order temperature coefficient of the offset voltage |
| A_{PGA} | The default gain of the PGA at room/initial temperature |
| V_{PGA} | The output voltage of the PGA |
| V_{o, PGA} | The input referred offset of the PGA |
| TC_{PGA} | The temperature coefficient of A_{PGA} |
| VR_{ADC} | The reference voltage of the ADC |
| V_{o, ADC} | The input referred offset of the ADC |
| N_{ADC} | The ADC resolution |
| TC_{VRADC} | The temperature coefficient of VR_{ADC} |
| Vₜₑₘₚ | The output voltage of the on-chip temperature sensor |
| TCₜₑₘₚ | The temperature coefficient of the temperature meter |
| V_{O, temp} | The initial/room output voltage of the temperature meter |
| A_{PGAC} | The PGA gain after the calibration |

As shown in equation (1), the selected calibration parameters include bridge supply voltage temperature coefficient (V_{BR0}·(1+TC_{BR}·ΔT)), the first and second order temperature coefficient of the bridge sensitivity (S₀·(1+TC_{1,S}·ΔT+TC_{2,S}·ΔT²)), bridge sensitivity second order nonlinearity factor induced by bridge sensor pressure ((1+Kₛ·ΔP)·ΔP) and the first and second order temperature coefficient of the bridge sensor offset (V_{off,0}·(1+TC_{1,o}·ΔT+TC_{2,o}·ΔT²)). V_{off,0} is the bride sensor offset after analog coarse calibration processing which is described in more detail below. It should be noted that equation (1) illustrates an example pressure bridge sensor calibration curve equation for the selected calibration parameters and the parameters' up to second order nonlinearity, but the principle in present description is applicable to other types of bridge sensors such as magnetic bridge sensor, and other calibration parameters and nonlinearity higher than second order. Since the LDO voltage regulator 210 is designed to provide a constant voltage with linear temperature coefficient characteristic, the second order or higher temperature coefficients can be omitted from (V_{BR0}·(1+TC_{BR}·ΔT)). As seen from the description below, the linear or first order temperature coefficient of the bridge supply voltage can be wrapped into bridge sensor temperature coefficients, thus it simplifies the calibration calculation and improves the accuracy of the calibration.

Output 240 of the PGA 218 is

V_{PGA}=A_{PGA}·(1+TC′_{PGA}·ΔT)·V′ₛₑₙₛₑ+A_{PGA}·V_{o,PGA}=A_{PGA}·(1+TC_{PGA}·ΔT)·Vₛₑₙₛₑ (2)

Where TC′_{PGA} and V′ₛₑₙₛₑ are the temperature coefficients of the PGA 218 gain and the sensor offset voltage. TC_{PGA} and Vₛₑₙₛₑ are the equivalent temperature coefficients and offset voltage after taking PGA's offset into consideration.

Combining (1) and (2), the output 246 of the ADC 222 becomes:

$$\begin{matrix}M \approx {2}^{{N}_{ADC}} \cdot ( \frac{{V}_{PGA}}{{VR}_{ADC} \cdot ( 1 + {TC}_{VRADC} \cdot Δ T )} + {V}_{o , ADC} ) \\ = {2}^{{N}_{ADC}} \cdot \{ \frac{1}{{VR}_{ADC} \cdot ( 1 + {TC}_{VRADC} \cdot Δ T )} \cdot \\ {A}_{PGA} \cdot ( 1 + {TC}_{PGA} \cdot Δ T ) • [ {V}_{BR 0} \cdot ( 1 + {TC}_{BR} \cdot Δ T ) • \\ {S}_{0} \cdot ( 1 + {TC}_{1 , S} \cdot Δ T + {TC}_{2 , S} \cdot Δ {T}^{2} ) \cdot \\ ( 1 + {K}_{s} \cdot Δ P ) \cdot Δ P + {V}_{off , 0} • \\ ( 1 + {TC}_{1 , o} \cdot Δ T + {TC}_{2 , o} \cdot Δ {T}^{2} ) ] + {V}_{o , ADC} \}\end{matrix} \qquad ( 3 )$$

After Taylor expansion, an equivalent polynomial expression, represented as a function of ΔT and ΔP is:

$$\begin{matrix}M \approx \frac{{2}^{{N}_{ADC}} \cdot {A}_{PGA}}{{VR}_{ADC}} \cdot [ {V}_{BR 0} {•S}_{0} \cdot ( 1 + {TC}_{1 , S} \cdot Δ T + {TC}_{2 , S} \cdot Δ {T}^{2} ) • \\ ( 1 + {K}_{s} \cdot Δ P ) \cdot Δ P + {V}_{off , 0} \cdot ( 1 + {TC}_{1 , o} \cdot Δ T + {TC}_{2 , o} \cdot Δ {T}^{2} ) ] \\ = {2}^{{N}_{ADC}} \cdot {A}_{PGA} \cdot [ \frac{{V}_{BR 0} \cdot {S}_{0}}{{VR}_{ADC}} • ( 1 + {TC}_{1 , S} \cdot Δ T + {TC}_{2 , S} \cdot Δ {T}^{2} ) • \\ ( 1 + {K}_{s} \cdot Δ P ) \cdot Δ P + \frac{{V}_{off , 0}}{{VR}_{ADC}} • ( 1 + {TC}_{1 , o} \cdot Δ T + {TC}_{2 , o} \cdot Δ {T}^{2} ) ]\end{matrix} \qquad ( 4 )$$

As seen, in equation (4), TC_{VRADC}, TC_{PGA} and V_{o,ADC} in equation (3) are wrapped into the various temperature coefficients, and the higher order terms are also omitted. Specifically bridge supply voltage's first order temperature coefficient TC_{BR} is also being wrapped into the various bridge sensor temperature coefficients. This is made possible by deliberately designing the bridge supply voltage to be a constant voltage with linear temperature coefficient characteristic.

Defining

$${F}_{s} = {2}^{{N}_{ADC}} \cdot \frac{{V}_{BR 0} \cdot {S}_{0}}{{VR}_{ADC }}$$

$${F}_{o} = {2}^{{N}_{ADC}} \cdot \frac{{V}_{off , 0}}{{VR}_{ADC }}$$

$${F}_{Ks} = {F}_{S} \cdot {K}_{s}$$

Equation (4) becomes

M=A_{PGA}·[Fₛ·(1+TC_{1,S}·ΔT+TC_{2,S}·ΔT²)·(1+Kₛ·ΔP)·ΔP+Fₒ·(1+TC_{1,o}·ΔT+TC_{2,o}·ΔT²)] (5)

The temperature measurement 242 from the on-chip temperature sensor 212 can be quantized as:

$$\begin{matrix}{V}_{temp} = {V}_{o , temp} \cdot ( 1 + {TC}_{temp} \cdot Δ T ) & ( 6 ) \\ M = {2}^{N} \cdot \frac{{V}_{o , temp}}{{VR}_{ADC}} \cdot ( 1 + {TC}_{temp} \cdot Δ T ) & ( 7 )\end{matrix}$$

Given selected calibration parameters and calibration curve equations represented above in equations (1)-(7), the calibration coefficients as defined in equations (1)-(7) can be obtained via a calibration procedure described below in FIG. 2.

The calibration procedure includes an analog coarse calibration phase and a digital fine calibration phase. Referring to FIG. 2, the analog coarse calibration phase starts (300) by setting the temperature to the environmental temperature, thus ΔT=0, and setting the pressure to the initial environmental pressure, thus ΔP=0, and initializing the register value of the offset DAC 232: ioff=1 and initializing the register value of the PGA 218: ipga=1. The bridge sensor offset is amplified by PGA 218 and quantized by ADC 222 which is measured as 246—the output of the ADC. Denoting the measured sensor offset signal 246 as MOFFS (302). Similarly, the quantized temperature measurement 242, outputted from ADC 222 is denoted as MT1 (310).

In operation, the coarse calibration phase monitors whether ADC sensor offset MOFFS changes sign (304). If the sign of MOFFS doesn't change, the register value of the offset DAC 232 is incremented (306) and the procedure goes back to measure the new ADC sensor offset MOFFS (302). If the sign of MOFFS changes, the coarse offset of the sensor is identified. The ADC sensor offset is measured at M1, and the corresponding input 250 to the offset DAC 232 is NVOFFS_M1. It will be used to generate the added signals 252 and 254.

The calculated value 250 for offset DAC 232 can be programmed into the offset register of the on-chip memory component 216 via digital interface 230 as described above.

After the coarse calibration phase sets the offset DAC 232 input using ioff=NVOFFS_M1, NVOFFS_M1 is used to program the offset DAC 232 and the ADC sensor output is then measured as M2._The coarse calibration phase moves on to the digital fine calibration phase I (330). Equation (5) then becomes:

$$\begin{matrix}M = {A}_{PGA} \cdot [ {F}_{s} \cdot ( 1 + {TC}_{1 , S} \cdot Δ T + {TC}_{2 , S} \cdot Δ {T}^{2} ) • ( 1 + {K}_{s} \cdot Δ P ) \cdot \\ Δ P + {F}_{o} • ( 1 + {TC}_{1 , o} \cdot Δ T + {TC}_{2 , o} \cdot Δ {T}^{2} ) + V offs ] \\ = {A}_{PGA} \cdot [ {F}_{s} • ( 1 + {TC}_{1 , S} \cdot Δ T + {TC}_{2 , S} \cdot Δ {T}^{2} ) • ( 1 + {K}_{s} \cdot Δ P ) \cdot \\ Δ P + {F}_{O} • ( {TC}_{1 , o} \cdot Δ T + {TC}_{2 , o} \cdot Δ {T}^{2} ) ] + {M}_{2}\end{matrix} \qquad ( 8 )$$

Referring to FIG. 3, the digital calibration phase I starts the PGA 218 tuning process (330) by setting by setting ΔT=0, ΔP=2*ΔPs and ipga=1, measuring quantized output at ADC output port, the measured value is denoted as M_PGA (332). The procedure continues to compare M_PGA with a predetermined value Nth. Nth is a selected margin to accommodate variations due to factors such as temperature variance and other offsets which depends on the property of the bridge sensor. If M_PGA is within the margin Nth, PGA 218 gain register value ipga will be incremented (336) and the procedure continues to step 332 to measure ADC output. If M_PGA exceeds the margin Nth, PGA 218 gain setting (NPGA) will be set at the last ipga value: NPGA=ipga (338).

The fine calibration procedure will then, in the subsequent steps, set up various environments represented by the environmental temperatures and pressures to measure corresponding data points, which will then be used to calculate the calibration coefficients by fitting the calibration curve equations to the measured data points.

The digital fine calibration moves on to set ΔT=0 and ΔP=0, ipga=NPGA, and ioff=NVOFFS_M1, measuring quantized output at ADC output port, the measured value is denoted as M20 (340). The environment is then re-set at ΔT=0 and ΔP=Ps, ipga=NPGA, and ioff=NVOFFS_M1, measuring quantized output at ADC output port, the measured value is denoted as M3 (342). The environment is again re-set at ΔT=0 and ΔP=2*Ps, ipga=NPGA, and ioff=NVOFFS_M1, measuring quantized output at ADC output port, the measured value is denoted as M4 (344).

Using measured M3 and M4, equation (8) will turn into:

M₃=A_{PGA}·Fₛ·(1+Kₛ·ΔPₛ)+ΔPₛ+M₂ (9)

M₄=A_{PGA}·Fₛ·(2+4·Kₛ·ΔPₛ)·ΔPₛ+M₂ (10)

Combining equations (9) and (10) gives:

$$\begin{matrix}2 \cdot Δ {P}_{s} \cdot {A}_{PGA} \cdot {F}_{s} = 4 \cdot {M}_{3} - {M}_{4} - 3 \cdot {M}_{2} & ( 11 ) \\ {K}_{s} = \frac{2 \cdot {M}_{3} - {M}_{4} - {M}_{2}}{( {M}_{4} - 4 \cdot {M}_{3} + 3 \cdot {M}_{2} ) \cdot Δ {P}_{s}} & ( 12 )\end{matrix}$$

The PGA (218) gain can be calculated as

$${A}_{PGAC} = Δ {P}_{s} \cdot \frac{Nth * {2}^{N}}{{M}_{4} - {M}_{3}} \cdot {A}_{PGA} \qquad ( 13 )$$

The sensor offset as measured ADC output M20 from step 340 is correlated with PGA gain: M_{2O}=A_{PGAC}·(Fₒ+Voffs).

The environment is again re-set at ΔT=0 and ΔP=ΔPs, measuring quantized output at ADC output port, the measured value is denoted as M5 (346).

Using measured M5, equation (8) will turn into:

M₅=A_{PGAC}·Fₛ·(1+K_{S}·ΔPₛ)·ΔPₛ+M_{2O} (14)

Define:

$${F}_{G} = {A}_{PGAC} \cdot {F}_{s} = \frac{{M}_{5} - {M}_{20}}{( 1 + {K}_{S} \cdot Δ {P}_{s} ) \cdot Δ {P}_{s}} \qquad ( 15 )$$

Equation (8) further gives:

M=F_{G}·(1+TC_{1,S}·ΔT+TC_{2,S}·ΔT²)·(1+K_{S}·ΔP)·ΔP+A_{PGAC}·Fₒ·(TC_{1,o}·ΔT+TC_{2,o}·ΔT²)+M_{2O} (16)

Where F_{G},K_{S} and M_{2O} are variables and measurement from the previous description.

The procedure will subsequently move to the digital fine calibration phase II (350).

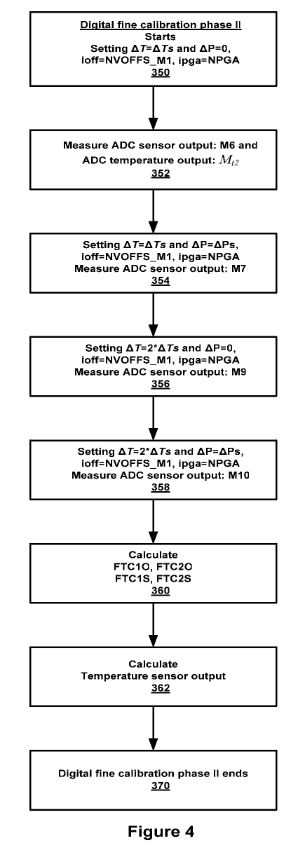

Referring to FIG. 4, the digital fine calibration phase II starts by setting ΔT=ΔTs and ΔP=0, ioff=NVOFFS_M1, and A_{PGA}=A_{PGAC} (350), measuring quantized sensor output at ADC output port, the measured value is denoted as M6 and measuring quantized temperature output at ADC output port, the measured value is denoted as Mₜ₂ (352).

We have:

M₆=A_{PGAC}·Fₒ·(TC_{1,o}·ΔTₛ+TC_{2,o}·ΔTₛ²)+M_{2O} (17)

Setting ΔT=ΔTs and ΔP=ΔPs, ioff=NVOFFS_M1, and A_{PGA}=A_{PGAC}, measuring quantized sensor output at ADC output port, the measured value is denoted as M7 (354).

Using measured M6 and M7, we have:

$$\begin{matrix}{M}_{7} = {F}_{G} • ( 1 + {TC}_{1 , S} \cdot Δ {T}_{s} + {TC}_{2 , S} \cdot Δ {T}_{s}^{2} ) • ( 1 + {K}_{S} \cdot Δ {P}_{s} ) \cdot \\ Δ {P}_{s} + {A}_{PGAC} \cdot {F}_{o} \cdot ( {TC}_{1 , o} \cdot Δ {T}_{s} + {TC}_{2 , o} \cdot Δ {T}_{s}^{2} ) + {M}_{2 O} \\ = {F}_{G} • ( 1 + {TC}_{1 , S} \cdot Δ {T}_{s} + {TC}_{2 , S} \cdot Δ {T}_{s}^{2} ) • ( 1 + {K}_{S} \cdot Δ {P}_{s} ) \cdot \\ Δ {P}_{s} + {M}_{6}\end{matrix} \qquad ( 18 )$$

Setting ΔT=2*ΔTs and ΔP=0, ioff=NVOFFS_M1, and A_{PGA}=A_{PGAC}, measuring quantized sensor output at ADC output port, the measured value is denoted as M9 (356).

Using measured M9, we have:

M₉=A_{PGAC}·Fₒ·(2·TC_{1,o}·ΔTₛ+4·TC_{2,o}·ΔTₛ²)+M_{2O} (19)

Setting ΔT=2*ΔTs and ΔP=ΔPs, ioff=NVOFFS_M1, and A_{PGA}=A_{PGAC}, measuring quantized sensor output at ADC output port, the measured value is denoted as M10 (358).

Using measured M9 and M10, we have:

$$\begin{matrix}{M}_{10} = {F}_{G} • ( 1 + 2 \cdot {TC}_{1 , S} \cdot Δ {T}_{s} + 4 \cdot {TC}_{2 , S} \cdot Δ {T}_{s}^{2} ) • \\ ( 1 + {K}_{S} \cdot Δ {P}_{s} ) \cdot Δ {P}_{s} + {A}_{PGAC} \cdot {F}_{o} \cdot \\ ( 2 \cdot {TC}_{1 , o} \cdot Δ {T}_{s} + 4 \cdot {TC}_{2 , o} \cdot Δ {T}_{s}^{2} ) + {M}_{2 O} \\ = {F}_{G} • ( 1 + 2 \cdot {TC}_{1 , S} \cdot Δ {T}_{s} + 4 \cdot {TC}_{2 , S} \cdot Δ {T}_{s}^{2} ) • \\ ( 1 + {K}_{S} \cdot Δ {P}_{s} ) \cdot Δ {P}_{s} + {M}_{9}\end{matrix} \qquad ( 20 )$$

After above stated measurements under various environmental conditions represented by environmental temperature and pressure, the calibration temperature coefficients for the selected parameters can thus be obtained as follows (360). By combining equations (17) and (19), the temperature coefficient of the offset can be obtained as:

$$\begin{matrix}\begin{matrix}{F}_{TC 1 , o} = {A}_{PGAC} \cdot {F}_{o} \cdot {TC}_{1 , o} \cdot Δ {T}_{s} \\ = 2 {M}_{6} - \frac{3}{2} {M}_{2 O} - \frac{{M}_{9}}{2}\end{matrix} & ( 21 ) \\ \begin{matrix}{F}_{TC 2 , o} = {A}_{PGAC} \cdot {F}_{o} \cdot {TC}_{2 , o} \cdot Δ {T}_{s}^{2} \\ = - {M}_{6} + \frac{1}{2} {M}_{2 O} + \frac{{M}_{9}}{2}\end{matrix} & ( 22 )\end{matrix}$$

By combining equations (18) and (20), the temperature coefficient of the sensitivity can be obtained as:

$$\begin{matrix}\begin{matrix}{F}_{TC 1 , S} = {TC}_{1 , s} \cdot Δ {T}_{s} \\ = ( 4 \cdot a - b - 3 ) \cdot \frac{1}{2} \\ = \frac{3 \cdot {M}_{2 O} - 3 \cdot {M}_{S} - {M}_{10} - 4 \cdot {M}_{6} + 4 \cdot {M}_{7} + {M}_{9}}{2 \cdot ( {M}_{5} - {M}_{2 O} )}\end{matrix} & ( 23 ) \\ \begin{matrix}{F}_{TC 2 , S} = {TC}_{2 , s} \cdot Δ {T}_{s}^{2} \\ = ( - 2 \cdot a + b + 1 ) \cdot \frac{1}{2} \\ = \frac{{M}_{5} - {M}_{2 O} + 2 \cdot {M}_{6} - 2 \cdot {M}_{7} - {M}_{9} + {M}_{10}}{2 \cdot ( {M}_{5} - {M}_{2 O} )}\end{matrix} & ( 24 )\end{matrix}$$

Where:

$$a = \frac{{M}_{7} - {M}_{6}}{{F}_{G} \cdot ( 1 + {K}_{s} \cdot Δ {P}_{s} ) \cdot Δ {P}_{s}} , \\ b = \frac{{M}_{10} - {M}_{9}}{{F}_{G} \cdot ( 1 + {K}_{s} \cdot Δ {P}_{s} ) \cdot Δ {P}_{s}}$$

Based on temperature measurements Mₜ₁ and Mₜ₂, the temperature sensor output from ADC can be obtained as (362):

$$M = {M}_{t 1} \cdot ( 1 + \frac{{M}_{t 2} - {M}_{t 1}}{Δ {T}_{s} \cdot {M}_{t 1}} \cdot Δ T ) \qquad ( 25 )$$

The digital fine calibration phase II process then ends (370).

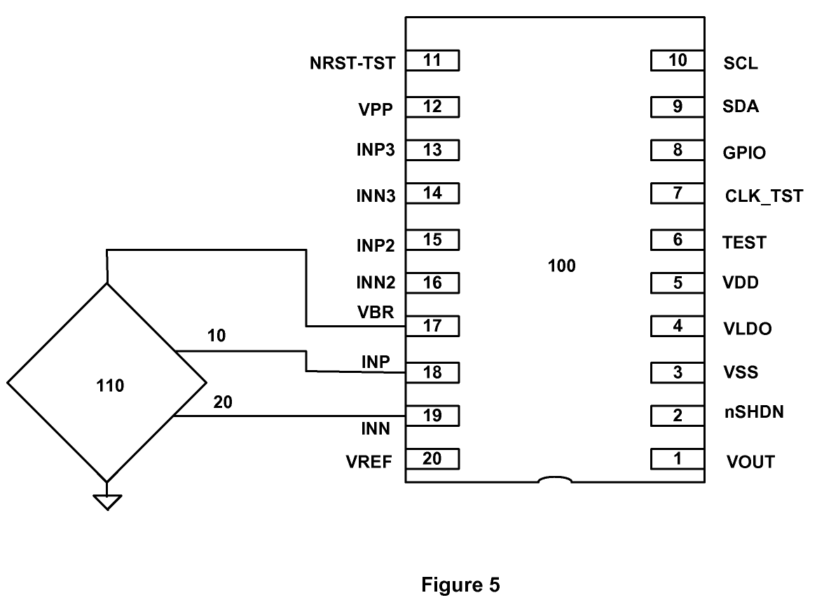

FIG. 5 shows an application scenario in which a bridge sensor 110 is connected to an example integrated circuit (IC) signal conditioning chip 100 for conditioning and calibrating the bridge sensor 110. The functional block diagram and, for simplicity, a partial set of pins from FIG. 5 are illustrated in FIG. 1. As shown in FIG. 3, the example integrated circuit (IC) signal conditioning chip 100 has 20 pins for connecting to and interfacing with various external sensors, analog/digital circuitry and communication device or computer for performing signal conditioning and processing functionalities. Table 2 provides the complete list of pins and their description:

TABLE 2
integrated circuit (IC) signal conditioning chip - pin description

| Order | | | |
|---|---|---|---|
| Number | Pin Name | Type | Description |
| 1 | VOUT | AO | Analog output of measurement result |
| 2 | nSHDN | AI | Shut down signal (low active) |
| 3 | VSS | P | Ground supply for analog processing |
| 4 | VLDO | AO | LDO output |
| 5 | VDD | P | Power supply for the digital processing |
| 6 | TEST | DI | When input “1”, the chip will |
| | | | use NRST_TST as its reset signal |
| | | | and CLK_TST as its system clock |
| 7 | CLK_TST | DI | Clock input in test mode |
| 8 | GPIO | BI | I/O pin used for test purpose |
| 9 | SDA | BI/OD | Data/address signal for I2C interface |
| 10 | SCL | DI | Select signal for I2C interface |
| 11 | NRST_TST | DI | Reset signal in test mode |
| 12 | VPP | P | Power supply for Digital memory |
| 13 | INP3 | AI | Positive input 3 for sensor |
| 14 | INN3 | AI | Negative input 3 for sensor |
| 15 | INP2 | AI | Positive input 2 for sensor |
| 16 | INN2 | AI | Negative input 2 for sensor |
| 17 | VBR | AO | Bias voltage output to sensor |
| 18 | INP | AI | Positive input for sensor |
| 19 | INN | AI | Negative input for sensor |
| 20 | VREF | AO | Reference voltage for test |

While greater details of the integrated circuit (IC) signal conditioning chip 100 have been described in connection with FIG. 1, FIG. 5 shows that the bridge sensor 110 connects its two differential inputs 10 and 20 to the positive input (pin 18) INP and negative input (pin 19) respectively. The bridge sensor 110 is driven by a on-chip voltage regulator from the integrated circuit (IC) signal conditioning chip 100 via the bias voltage output pin—VBR (pin 17).

While the description has been particularly shown and described with reference to specific exemplary embodiments, it is evident that those skilled in the art may now make numerous modifications of, departures from and uses of the specific apparatus and techniques herein disclosed. Consequently, other implementations are also within the scope of the following claims.

What is claimed is:

1. An integrated circuit (IC) for calibrating a bridge sensor, comprising:
a voltage regulator for providing a voltage to drive the sensor and the integrated circuit;
a temperature sensor for measuring a temperature of the environment;
a programmable gain amplifier having inputs connected to the sensor for receiving differential outputs of the sensor;
a programmable offset generator for performing analog coarse calibration of the bridge sensor offset by providing an offset value to the input of the programmable gain amplifier;
an analog multiplex selects either the programmable gain amplifier output or the environment temperature measurement from the temperature sensor as output;
a high resolution analog-to-digital converter quantizes the output of the analog multiplex;
a processor for performing digital fine calibration by calculating calibration coefficients for a selected set of parameters including the offset of the bridge sensor, temperature coefficients of the bridge sensor sensitivity and nonlinearity of the sensitivity;
a digital memory unit for storing the coarse calibration offset value and the calculated fine calibration coefficients.

2. The integrated circuit of claim 1 wherein the voltage regulator provide a constant voltage with linear temperature coefficient.

3. The integrated circuit of claim 1 wherein the programmable offset generator is a digital-to-analog converter.

4. The integrated circuit of claim 1 wherein the high resolution analog-to-digital converter has at least 18 bits.

5. The integrated circuit of claim 1 wherein the digital memory unit is chosen from the group consisting of an electrically erasable programmable ROM (EEPROM), a one-time programmable (OTP), and a multi-time programmable (MTP) memory.

6. The integrated circuit of claim 1 wherein the processor calculates the calibration coefficients based on a curve equation representing a relationship between bridge sensor output and environment variables including environment temperature.

7. The integrated circuit of claim 1 wherein the calculated calibration coefficients are stored in the digital memory unit as a look-up table.

8. The integrated circuit of claim 1 further comprises a circuitry for controlling the calculation steps and flow.

9. The integrated circuit of claim 1 wherein the offset value provides a calibrating signal summing with the sensor output differential output signals at the inputs of the programmable gain amplifier.

10. The integrated circuit of claim 1 wherein the offset value for coarse calibration is determined according to the full swing input of analog-to-digital converter.

11. The integrated circuit of claim 1 wherein the selected set of parameters comprises second order or higher nonlinearity of the parameters chosen from the group consisting of bridge supply, bridge bias, the programmable gain amplifier, offset, and digital-to-analog converter.

12. A method for calibrating a bridge sensor using an integrated circuit (IC), comprising:
providing a constant voltage to the sensor and the integrated circuit, wherein the voltage is from a voltage regulator residing on the integrated circuit;
adding an offset signal to the input of a programmable gain amplifier on the integrated circuit to the differential output of the bridge sensor, wherein the offset value is stored in a digital memory unit of the integrated circuit;
setting the integrated circuit environment variables to a plurality of values;
measuring, the quantized by an analog-to-digital converter, at least one of the differential output of the bridge sensor calibrated in the analog domain and amplified by the programmable gain amplifier and a temperature reading from a temperature sensor on the integrated circuit, to obtain a plurality of measurements corresponding to the plurality of environment variables;
calculating, in the digital domain, calibration coefficients for a selected set of parameters including the offset of the bridge sensor, temperature coefficients of the bridge sensor sensitivity and nonlinearity of the sensitivity;
storing the calculated calibration coefficients in the digital memory unit.

13. The method of claim 12 wherein the voltage from the voltage regulator has linear temperature coefficient characteristic.

14. The method of claim 12 wherein digital domain calculating is performed by fitting a curve representing a relationship between bridge sensor output and environment variables to the plurality of measurements.

15. The method of claim 12 wherein the calculated calibration coefficients are stored in the digital memory unit as a look-up table.

16. The method of claim 12 wherein the selected set of parameters comprises second order or higher nonlinearity of the parameters chosen from the group consisting of bridge supply, bridge bias, the programmable gain amplifier, offset, and digital-to-analog converter.
